(19) United States
(12) Patent Application Publication
(10) Pub. No.: US 2026/0065982 A1
(43) Pub. Date: Mar. 5, 2026

(54) SUB-THRESHOLD MONOSTABLE PUF CIRCUIT WITH SRAM FUNCTION AND ENTROPY SOURCE EXTRACTION FUNCTION

(71) Applicant: Wenzhou University, Zhejiang (CN)

(72) Inventors: Pengjun WANG, Zhejiang (CN); Mingze Ren, Zhejiang (CN); Bo CHEN, Zhejiang (CN); Ziyu Zhou, Zhejiang (CN); Hao Ye, Zhejiang (CN)

(73) Assignee: Wenzhou University, Zhejiang (CN)

(21) Appl. No.: 19/303,266

(22) Filed: Aug. 18, 2025

(30) Foreign Application Priority Data
Sep. 5, 2024 (CN) 202411237694.0

(51) Int. Cl. G11C 11/419; G11C 5/14; G11C 11/418

(52) U.S. Cl. CPC G11C 11/419; G11C 5/146; G11C 11/418

(57) ABSTRACT

A sub-threshold monostable PUF circuit with an SRAM function and an entropy source extraction function includes a mode configuration circuit, a decoding circuit, a PUF array and a reading circuit. The PUF array has a SRAM storage mode and a PUF mode for generating an entropy source voltage. The PUF array includes m*n PUF cells and n pre-charge modules. Each PUF cell includes a first PMOS transistor, a second PMOS transistor, a third PMOS transistor, a first NMOS transistor, a second NMOS transistor, a third NMOS transistor, a fourth NMOS transistor, a fifth NMOS transistor and a sixth NMOS transistor. The monostable PUF array formed by PUF cells is constructed only by adding a first PMOS transistor, a first NMOS transistor and a fourth NMOS transistor in each SRAM cell of an original SRAM storage array of IoT equipment.

### CROSS-REFERENCE TO RELATED APPLICATION

This application claims the priority benefit of China application serial no. 202411237694.0, filed on Sep. 5, 2024. The entirety of the above-mentioned patent application is hereby incorporated by reference herein and made a part of this specification.

### BACKGROUND

### Technical Field

The present invention relates to PUF circuits, in particular to a sub-threshold monostable PUF circuit with an SRAM function and an entropy source extraction function.

### Description of Related Art

Physical Unclonable Functions (PUFs) generate keys used for identity recognition and equipment authentication by means of process deviations generated in the silicon chip fabrication process and effectively improve the security of Internet of Things (IoT) equipment. An SRAM storage array formed by a plurality of SRAM cells, which are distributed in an array, is configured in the IoT equipment, wherein each SRAM cell is formed by two cross-coupled inverters. After the SRAM storage array is powered on, each SRAM cell has a power-on state at a low level 0 or a power-on state at a high level 1, and the power-on state of each SRAM cell is determined by the process deviation of the SRAM cell.

An SRAM PUF circuit, as a PUF circuit that is widely used in the IoT equipment, adopts the SRAM storage array in the IoT equipment as a PUF array, the SRAM cells in the SRAM storage array are used as PUF cells in the PUF array to generate an entropy source voltage for extracting PUF responses, such that it is unnecessary to specially design an extra PUF array for generating the entropy source voltage, thus greatly reducing hardware overheads of the IoT equipment and realizing wide application of the SRAM PUF circuit in the IoT equipment.

However, because each bit of a PUF response of the SRAM PUF circuit is extracted by means of the entropy source voltage generated by means of the bistable characteristic of the cross-coupled inverters in the power-on process of the SRAM cells, in a case where the process deviation of the SRAM cells is small, a power-on result (i.e., the entropy source voltage) may be determined by environmental disturbance rather than the process deviation, leading to poor reliability of extracted PUF responses. Thus, the SRAM PUF circuit is poor in reliability, which will exert a negative impact on identity recognition and equipment authentication of the IoT equipment.

To improve the security of identity recognition and equipment authentication of the IoT equipment, some researchers proposed other PUF circuits, which resign the PUF cells and the PUF array rather than using the SRAM storage array as the PUF array. The PUF cells of these PUF circuits is monostable, and the entropy source voltage used for extracting PUF responses will be determined by the process deviation of the SRAM cells even if the process deviation is small, which allows for high reliability of these PUF circuits. However, because the PUF array has a large size, high hardware overheads will be caused when these PUF circuits are applied to the IoT equipment, as compared with the SRAM PUF circuit.

### SUMMARY

The technical issue to be settled by the present invention is to provide a sub-threshold monostable PUF circuit with an SRAM function and an entropy source extraction function, which has high reliability and low overall hardware overheads.

The technical solution adopted by the present invention to settle the above technical issue is as follows: a sub-threshold monostable PUF circuit with an SRAM function and an entropy source extraction function includes a mode configuration circuit, a decoding circuit, a PUF array and a reading circuit. The PUF array has a conventional SRAM storage mode and a PUF mode for generating an entropy source voltage. The PUF array includes m*n PUF cells and n pre-charge modules, wherein * is a multiplication operator, m=2^{P}, n=2^{K}, P and K are positive integers; the m*n PUF cells are distributed in m rows and n columns, the n pre-charge modules are distributed in one row and n columns, and each PUF cell has a left bit line port, a right bit line port, a first mode configuration port, a second mode configuration port, a third mode configuration port and a word line port; each pre-charge module has a left pre-charge port, a right pre-charge port and a pre-charge control port; the left bit line ports of the m PUF cells in an i^{th} column are connected to the left pre-charge port of the pre-charge module in the i^{th} column, with a connecting line forming an i^{th} left bit line of the PUF array, which is denoted as BL[i−1], and i=1, 2, . . . , n; the right bit line ports of the m PUF cells in the i^{th} column are connected to the right pre-charge port of the pre-charge module in the i^{th} column, with a connecting line forming an i^{th} right bit line of the PUF array, which is denoted as BLB[i−1]; the first mode configuration ports of the m PUF cells in the i^{th} column are connected together, with a connecting line forming an i^{th} first mode configuration line of the PUF array, which is denoted as Vu[i−1]; the second mode configuration ports of the m PUF cells in the i^{th} column are connected together, with a connecting line forming an i^{th} second mode configuration line of the PUF array, which is denoted as Vd[i−1]; the third mode configuration ports of the m PUF cells in the i^{th} column are connected together, with a connecting line forming an i^{th} third mode configuration line of the PUF array, which is denoted as E[i−1]; the word line ports of the n PUF cells in a j^{th} row are connected together, with a connecting line forming a j^{th} word line of the PUF array, which is denoted as WL[j−1], and j=1, 2, . . . , m; and the pre-charge control ports of the n pre-charge modules are connected together, and a connecting terminal thereof is a pre-charge control port of the PUF array. The mode configuration circuit has a mode selection port, n first mode signal output ports and n second mode signal output ports, wherein a mode selection signal S is accessed by the mode selection port of the mode configuration circuit, and under the control of the mode selection signal S, the n first mode signal output ports and the n second mode signal output ports of the mode configuration circuit respectively generate corresponding n-bit mode configuration signals and output the n-bit mode configuration signals. In a case where the mode selection signal S is a low level 0 and signals accessed by the n third mode configuration lines of the PUF array are all the low level 0, the PUF array is configured as the conventional SRAM storage mode, and at this moment, each of the PUF cells works in the conventional SRAM storage mode. In a case where the mode selection signal S is a high level 1 and the signals accessed by the n third mode configuration lines of the PUF array are all the high level 1, the PUF array is configured as the PUF mode for generating the entropy source voltage, and at this moment, each of the PUF cells works in the PUF mode for generating the entropy source voltage. The decoding circuit has m output terminals and is configured to convert an address signal input thereto from the outside into an m-bit row selection signal, which is output by the m output terminals of the decoding circuit in one-to-one correspondence; and only one bit of the m-bit row selection signal is the high level 1, and the other bits of the m-bit row selection signal are all the low level 0. The reading circuit has a reference voltage input terminal, n left input ports, n right input ports, n left output ports and n right output ports. The n first mode signal output ports of the mode configuration circuit are connected to the n first mode configuration lines of the PUF array in one-to-one correspondence, the n second mode configuration output ports of the mode configuration circuit are connected to the n second mode configuration lines of the PUF array in one-to-one correspondence, n mode configuration signals from the outside are accessed by the n third mode configuration lines of the PUF array, the m output terminals of the decoding circuit are connected to the m word lines of the PUF array in one-to-one correspondence, the n left input ports of the reading circuit are connected to the n left bit lines of the PUF array in one-to-one correspondence, and the n right input ports of the reading circuit are connected to the n right bit lines of the PUF array in one-to-one correspondence. In a case where a high level 1 is accessed by one word line of the PUF array, a row of PUF cells corresponding to the word line are selected, an i^{th} PUF cell in the row outputs a voltage at the left bit line port thereof to an i^{th} left input port of the reading circuit by means of the i^{th} left bit line, the i^{th} PUF cell in the row outputs a voltage at the right bit line port thereof to an i^{th} right input port of the reading circuit by means of the i^{th} right bit line, and the reading circuit respectively compares the voltage accessed by the i^{th} left input port thereof and the voltage accessed by the i^{th} right input port thereof with a reference voltage accessed by the reference voltage input terminal thereof. If the voltage accessed by the i^{th} left input port of the reading circuit is greater than the reference voltage accessed by the reference voltage input terminal of the reading circuit, a digital signal 0 is output by an i^{th} left input port of the reading circuit; otherwise, a digital signal 1 is output by the i^{th} left input port of the reading circuit. If the voltage accessed by the i^{th} right input port of the reading circuit is greater than the reference voltage accessed by the reference voltage input terminal of the reading circuit, a digital signal 1 is output by an i^{th} right input port of the reading circuit; otherwise, a digital signal 0 is output by the i^{th} right input port of the reading circuit. Each PUF cell includes a first PMOS transistor, a second PMOS transistor, a third PMOS transistor, a first NMOS transistor, a second NMOS transistor, a third NMOS transistor, a fourth NMOS transistor, a fifth NMOS transistor and a sixth NMOS transistor, wherein a gate of the first PMOS transistor is the first mode configuration port of the PUF cell; a supply voltage VDD is accessed by a source of the first PMOS transistor; a drain of the first PMOS transistor, a source of the second PMOS transistor and a source of the third PMOS transistor are connected; a gate of the second PMOS transistor, a gate of the second NMOS transistor, a drain of the third PMOS transistor, a drain of the third NMOS transistor, a drain of the fourth NMOS transistor and a drain of the sixth NMOS transistor are connected; a drain of the second PMOS transistor, a drain of the second NMOS transistor, a gate of the third PMOS transistor, a gate of the third NMOS transistor, a source of the fourth NMOS transistor and a drain of the fifth NMOS transistor are connected; a source of the first NMOS transistor is grounded VSS; a drain of the first NMOS transistor, a source of the second NMOS transistor and a source of the third NMOS transistor are connected; a gate of the first NMOS transistor is the second mode configuration port of the PUF cell; a gate of the fourth NMOS transistor is the third mode configuration port of the PUF cell; a gate of the fifth NMOS transistor and a gate of the sixth NMOS transistor are connected, and a connecting terminal thereof is the word line port of the PUF cell; the source of the fifth NMOS transistor is the left bit line port of the PUF cell; and a source of the sixth NMOS transistor is the right bit line port of the PUF cell.

Each pre-charge module includes a fourth PMOS transistor, a fifth PMOS transistor and a sixth PMOS transistor, wherein a gate of the fourth PMOS transistor, a gate of the fifth PMOS transistor and a gate of the sixth PMOS transistor are connected, and a connecting terminal thereof is the pre-charge control port of the pre-charge module; half of a supply voltage VDD/2 is accessed by a source of the fourth PMOS transistor and a source of the fifth PMOS transistor; a drain of the fourth PMOS transistor and a source of the sixth PMOS transistor are connected, and a connecting terminal thereof is the left pre-charge port of the pre-charge module; and a drain of the fifth PMOS transistor and a drain of the sixth PMOS transistor are connected, and a connecting terminal thereof is the right pre-charge port of the pre-charge module.

The mode configuration circuit includes a bias voltage source and n mode selectors, wherein the bias voltage source has a first bias voltage output port and a second bias voltage output port; each mode selector has a low level access port, a high level access port, a first bias voltage access port, a second bias voltage access port, a mode selection signal port, a first mode signal output port and a second mode signal output port; a low level 0 is accessed by the low level access port of each mode selector, and a high level 1 is accessed by the high level access port of each mode selector; the first bias voltage output port of the bias voltage source is connected to the first bias voltage access ports of the n mode selectors; the second bias voltage output port of the bias voltage source is connected to the second bias voltage access ports of the n mode selectors; the mode selection signal ports of the n mode selectors are connected, and a connecting terminal thereof is the mode selection port of the mode configuration circuit; the first mode signal output ports of the n mode selectors are used as the n first mode signal output ports of the mode configuration circuit; and the second mode signal output ports of the n mode selectors are used as the n second mode signal output ports of the mode configuration circuit.

The bias voltage source includes a seventh PMOS transistor, an eighth PMOS transistor, a seventh NMOS transistor and an eighth NMOS transistor, wherein a supply voltage VDD is accessed by a source of the seventh PMOS transistor; a gate of the seventh PMOS transistor, a drain of the seventh PMOS transistor and a source of the eighth PMOS transistor are connected, and a connecting terminal thereof is the first bias voltage output port of the bias voltage source; a gate of the eighth PMOS transistor, a drain of the eighth PMOS transistor, a drain of the eighth NMOS transistor and a gate of the eighth NMOS transistor are connected; a gate of the seventh NMOS transistor, a drain of the seventh NMOS transistor and a source of the eighth NMOS transistor are connected, and a connecting terminal thereof is the second bias voltage output port of the bias voltage source; and a source of the seventh NMOS transistor is grounded VSS.

Each mode selector includes two multiplexers, wherein each multiplexer has a first input port, a second input port, a selection terminal and an output terminal; in a case where a high level is accessed by the selection terminal, the first input port is connected to the output terminal; in a case where a low level is accessed by the selection terminal, the second input port is connected to the output terminal; and the two multiplexers are referred to as a first multiplexer and a second multiplexer, respectively, the first input port of the first multiplexer is the first bias voltage access port of the mode selector, the second input port of the first multiplexer is the low level access port of the mode selector, the first input port of the second multiplexer is the second bias voltage access port of the mode selection, and the second input port of the second multiplexer is the high level access port of the mode selector.

Compared with the prior art, the present invention has the following advantages: the sub-threshold monostable PUF circuit with an SRAM function and an entropy source extraction function is constructed by the mode configuration circuit, the decoding circuit, the PUF array and the reading circuit; the PUF array has a conventional SRAM storage mode and a PUF mode for generating an entropy source voltage; the PUF array includes m*n PUF cells and n pre-charge modules; and each PUF cell includes the first PMOS transistor, the second PMOS transistor, the third PMOS transistor, the first NMOS transistor, the second NMOS transistor, the third NMOS transistor, the fourth NMOS transistor, the fifth NMOS transistor and the sixth NMOS transistor. In a case where the PUF array is configured as the PUF mode for generating the entropy source voltage, the n first mode output ports of the mode configuration circuit output a same voltage signal, which is denoted as V_{b1}, and the n second mode output ports of the mode configuration circuit also output a same voltage signal, which is denoted as V_{b2}, wherein V_{b1} is greater than V_{b2}, V_{b1} is less than a threshold voltage of the first PMOS transistor, and V_{b2} is less than a threshold voltage of the first NMOS transistor; at this moment, the voltage signal V_{b1} is accessed by the first mode configuration port of each PUF cell in the PUF array, the voltage signal V_{b2} is accessed by the second mode configuration port of each PUF cell in the PUF array, and each PUF cell in the PUF array works in the PUF mode for generating the entropy source voltage; at this moment, in each PUF cell, the voltage signal V_{b1} is accessed by the gate of the first PMOS transistor, and the voltage signal V_{b2} is accessed by the gate of the first NMOS transistor; because V_{b1} is less than the threshold voltage of the first PMOS transistor and V_{b2} is less than the threshold voltage of the first NMOS transistor, the first PMOS transistor and the first NMOS transistor are not turned on and located in a deep sub-threshold region, currents across the first PMOS transistor and the first NMOS transistor are weak sub-threshold currents, the sub-threshold current across the first PMOS transistor is denoted as I_{P1}, the sub-threshold current across the first NMOS transistor is denoted as I_{N1}, and I_{P1} and I_{N1} are merely at the nA level; because the second PMOS transistor and the third PMOS transistor are connected in parallel and the first PMOS transistor is connected in series with the second PMOS transistor and the third PMOS transistor, the current I_{P1} across the first PMOS transistor is equal to the sum of a current I_{P2} across the second PMOS transistor and a current I_{P3} across the third PMOS transistor according to the Kirchhoff's Current Law, and limited by the current I_{P1}, the current I_{P2} and the current I_{P3} are also weak sub-threshold currents, which force the second PMOS transistor and the third PMOS transistor to enter the deep sub-threshold region; and under the combined action of the currents I_{P1}, I_{P2} and I_{P3}, a matching voltage V₁ is generated at a joint of the drain of the first PMOS transistor, the source of the second PMOS transistor and the source of the third PMOS transistor. Similarly, the current I_{N1} across the first NMOS transistor is equal to the sum of a current I_{N2} across the second NMOS transistor and a current I_{N3} across the third NMOS transistor, and limited by the current I_{N1}, the currents I_{N2} and I_{N3} are also weak sub-threshold currents, which force the second NMOS transistor and the third NMOS transistor to enter the deep sub-threshold region; under the combined action of the currents I_{N1}, I_{N2} and I_{N3}, a matching voltage V₂ is generated at a joint of the drain of the first NMOS transistor, the source of the second NMOS transistor and the source of the third NMOS transistor; the sum of the current I_{P2} across the second PMOS transistor and the current I_{P3} across the third PMOS transistor is equal to the sum of the current I_{N2} across the second NMOS transistor and a current I_{N4} across the fourth NMOS transistor, and an entropy source voltage V_{M} in the PUF mode is generated at a joint of the drain of the second PMOS transistor, the drain of the third PMOS transistor, the drain of the second NMOS transistor and the drain of the third NMOS transistor, in conjunction with the matching voltages V₁ and V₂; V_{M} is related to process parameters of the first PMOS transistor, the second PMOS transistor, the third PMOS transistor, the first NMOS transistor, the second NMOS transistor and the third NMOS transistor, process deviations are inevitably introduced in the actual chip fabrication process, and these process deviations, particularly the difference between threshold voltages, change randomly and are amplified by the source-induced barrier lowering effect, leading to a large voltage distribution of V_{M}. After each PUF cell in the PUF array generates the entropy source voltage, all the pre-charge modules of the PUF array perform a pre-charge operation to refresh charges of all the left bit lines and all the right bit lines of the PUF array to keep voltages of all the left bit lines and all the right bit lines of the PUF array equal, and then, all the pre-charge modules stop the pre-charge operation; the decoding circuit outputs an m-bit row selection signal to select n PUF cells in one row of the PUF array, the entropy source voltage V_{M} generated by each of the selected PUF cells is transmitted by the fifth NMOS transistor and the sixth NMOS transistor to the left bit line and the right bit line connected to the PUF cell, at this moment, the entropy source voltage generated by the PUF cell, in the i^{th} column, of the n selected PUF cells is accessed by the i^{th} right bit line and the i^{th} left bit line of the PUF array, corresponding entropy source voltages are accessed by each left input port and each right input port of the reading circuit, and the reading circuit digitizes the entropy source voltages accessed by the n left input ports and the n right input ports to obtain a PUF response, which is then output. After the PUF response is output, all the pre-charge modules of the PUF array perform the pre-charge operation again to refresh the charges of all the left bit lines and all the right bit lines of the PUF array to keep the voltages of all the left bit lines and all the right bit lines of the PUF array equal, and then, all the pre-charge modules stop the pre-charge operation then, the decoding circuit outputs again an m-bit row selection signal; and this process is repeated until a desired number of PUF responses are output. In a case where the PUF array is configured as the conventional SRAM storage mode, the n first mode output ports of the mode configuration circuit output a low level 0, and the n second mode output ports of the mode configuration circuit output a high level 1; at this moment, the low level 0 is accessed by the first mode configuration ports of all the PUF cells in the PUF array, and the high level 1 is accessed by the second mode configuration ports of all the PUF cells in the PUF array; at this moment, the first PMOS transistor and the first NMOS transistor are turned on completely to be equivalent to a wire, and each PUF cell in the PUF array works in the conventional SRAM storage mode; the second PMOS transistor, the third PMOS transistor, the second NMOS transistor and the third NMOS transistor in each PUF cell form a pair of cross-coupled inverters with a positive feedback function, wherein a joint of the drain of the second PMOS transistor and the drain of the second NMOS transistor is a left data storage node, which is denoted as Q; a joint of the drain of the third PMOS transistor and the drain of the third NMOS transistor is a right data storage node, which is denoted as QB; the PUF cells are equivalent to conventional SRAM cells; when a data write operation is performed, an external write circuit transmits an n-bit data signal to the n left bit lines and the n right bit lines of the PUF array, the decoding circuit outputs an m-bit row selection signal to select n PUF cells in one row of the PUF array, and each of the selected PUF cells transmits data to the left storage node Q and the right storage node QB of each PUF cell working in the conventional SRAM storage mode by means of the fifth NMOS transistor and the sixth NMOS transistor; when a hold operation is performed, the decoding circuit does not output a signal, the fifth NMOS transistor and the sixth NMOS transistor of each PUF cell in the PUF array are turned off, and data (voltages) on the left storage node Q and the right storage node QB are held under the effect of positive feedback of the cross-coupled inverters; before data reading, all the pre-charge modules of the PUF array perform the pre-charge operation to refresh charges of all the left bit lines and all the right bit lines of the PUF array to keep voltages of all the left bit lines and all the right bit lines equal, and then, all the pre-charge modules stop the pre-charge operation; the decoding circuit outputs an m-bit row selection signal to select n PUF cell in one row of the PUF array; in each of the selected PUF cells, the data are transmitted from the left storage node Q and the right storage node QB to the left bit line and the right bit line connected to the PUF cell by means of the fifth NMOS transistor and the sixth NMOS transistor; at this moment, the data on the left storage node Q and the right storage node QB of the PUF cell, in the i^{th} column, of the n selected PUF cells are accessed by the i^{th} left bit line and the i^{th} right bit line of the PUF array, and corresponding data are accessed by each left input port and each right input port of the reading circuit; the reading circuit digitizes data currently accessed by the n left input ports and the n right input ports thereof into corresponding data, which are then output. After the data are output, all the pre-charge modules of the PUF array perform the pre-charge operation again to refresh the charges of all the left bit lines and all the right bit lines of the PUF array to keep the voltages of all the left bit lines and all the right bit lines of the PUF array equal, and then, all the pre-charge modules stop the pre-charge operation; then, the decoding circuit outputs again an m-bit row selection signal; and the process is repeated until all data are read. According to the sub-threshold monostable PUF circuit with an SRAM function and an entropy source extraction function provided by the present invention, a PUF array does not need to be additionally designed, the monostable PUF array formed by PUF cells is constructed only by adding a first PMOS transistor, a first NMOS transistor and a fourth NMOS transistor in each SRAM cell of an original SRAM storage array of IoT equipment, and the function of the original SRAM storage array is not affected. Thus, the sub-threshold monostable PUF circuit with an SRAM function and an entropy source extraction function provided by the present invention has high reliability and low overall hardware overheads.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a modular block diagram of a sub-threshold monostable PUF circuit with an SRAM function and an entropy source extraction function according to the present invention;

FIG. 2 is a structural block diagram of a PUF array of the sub-threshold monostable PUF circuit with an SRAM function and an entropy source extraction function according to the present invention;

FIG. 3 is a circuit diagram of a PUF cell of the sub-threshold monostable PUF circuit with an SRAM function and an entropy source extraction function according to the present invention;

FIG. 4 is an equivalent circuit diagram of the PUF cell operating in a PUF mode of the sub-threshold monostable PUF circuit with an SRAM function and an entropy source extraction function according to the present invention;

FIG. 5 is an equivalent circuit diagram of the PUF cell operating in a bistable data storage mod, of the sub-threshold monostable PUF circuit with an SRAM function and an entropy source extraction function according to the present invention;

FIG. 6 is a circuit diagram of a pre-charge circuit of the sub-threshold monostable PUF circuit with an SRAM function and an entropy source extraction function according to the present invention;

FIG. 7 is a structural block diagram of a mode configuration circuit of the sub-threshold monostable PUF circuit with an SRAM function and an entropy source extraction function according to the present invention;

FIG. 8 is a circuit diagram of a bias voltage source of the sub-threshold monostable PUF circuit with an SRAM function and an entropy source extraction function according to the present invention;

FIG. 9 is a circuit diagram of a mode selection circuit of the sub-threshold monostable PUF circuit with an SRAM function and an entropy source extraction function according to the present invention;

FIG. 10 is a distribution histogram of the inter-Hamming distance of PUF responses of the sub-threshold monostable PUF circuit with an SRAM function and an entropy source extraction function according to the present invention;

FIG. 11 is a diagram of the variation, with temperature and voltage, the bit error rate of the sub-threshold monostable PUF circuit with an SRAM function and an entropy source extraction function according to the present invention.

### DESCRIPTION OF THE EMBODIMENTS

The present invention is described in further detail below in conjunction with accompanying drawings and embodiments.

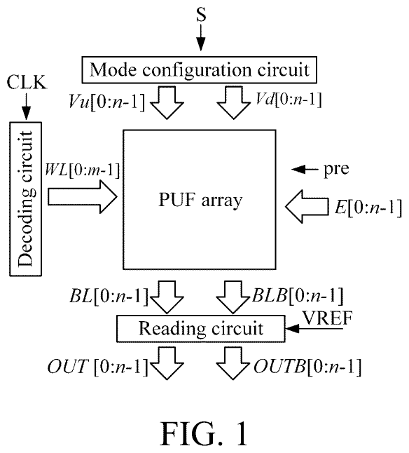

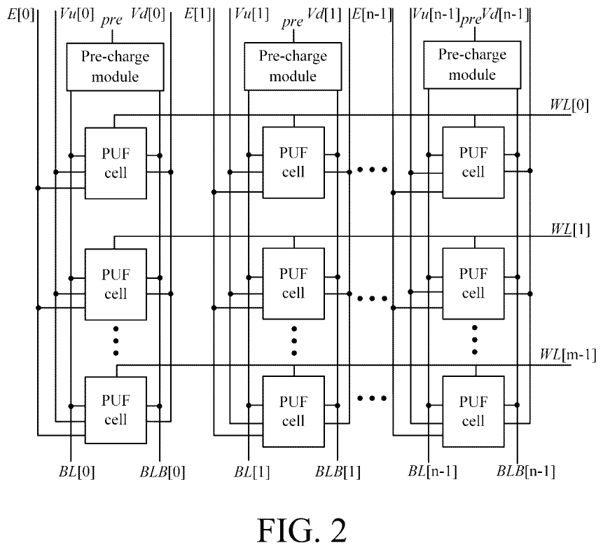

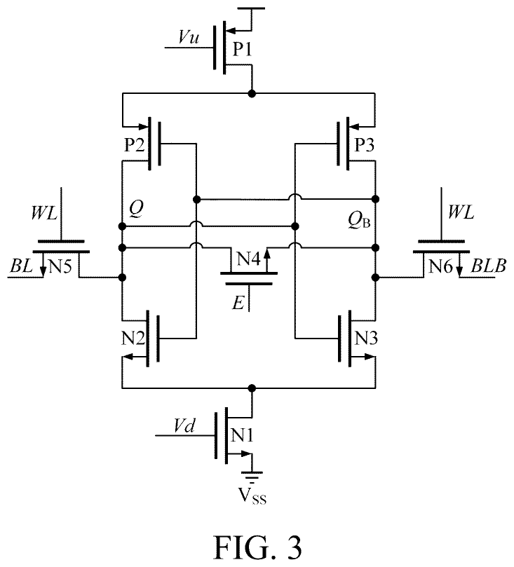

Embodiment 1: As shown in FIG. 1, a sub-threshold monostable PUF circuit with an SRAM function and an entropy source extraction function includes a mode configuration circuit, a decoding circuit, a PUF array and a reading circuit. The PUF array has a conventional SRAM storage mode and a PUF mode for generating an entropy source voltage. The PUF array includes m*n PUF cells and n pre-charge modules, wherein * is a multiplication operator, m=2^{P}, n=2^{K}, P=5, and K=3; the m*n PUF cells are distributed in m rows and n columns, the n pre-charge modules are distributed in one row and n columns, and each PUF cell has a left bit line port, a right bit line port, a first mode configuration port, a second mode configuration port, a third mode configuration port and a word line port; each pre-charge module has a left pre-charge port, a right pre-charge port and a pre-charge control port; the left bit line ports of the m PUF cells in an i^{th} column are connected to the left pre-charge port of the pre-charge module in the i^{th} column, with a connecting line forming an i^{th} left bit line of the PUF array, which is denoted as BL[i−1], and i=1, 2, . . . , n; the right bit line ports of the m PUF cells in the i^{th} column are connected to the right pre-charge port of the pre-charge module in the i^{th} column, with a connecting line forming an i^{th} right bit line of the PUF array, which is denoted as BLB[i−1]; the first mode configuration ports of the m PUF cells in the i^{th} column are connected together, with a connecting line forming an i^{th} first mode configuration line of the PUF array, which is denoted as Vu[i−1]; the second mode configuration ports of the m PUF cells in the i^{th} column are connected together, with a connecting line forming an i^{th} second mode configuration line of the PUF array, which is denoted as Vd[i−1]; the third mode configuration ports of the m PUF cells in the i^{th} column are connected together, with a connecting line forming an i^{th} third mode configuration line of the PUF array, which is denoted as E[i−1]; the word line ports of the n PUF cells in a j^{th} row are connected together, with a connecting line forming a j^{th} word line of the PUF array, which is denoted as WL[j−1], and j=1, 2, . . . , m; and the pre-charge control ports of the n pre-charge modules are connected, and a connecting terminal thereof is a pre-charge control port of the PUF array. The mode configuration circuit has a mode selection port, n first mode signal output ports and n second mode signal output ports, wherein a mode selection signal S is accessed by the mode selection port of the mode configuration circuit, and under the control of the mode selection signal S, the n first mode signal output ports and the n second mode signal output ports of the mode configuration circuit respectively generate corresponding n-bit mode configuration signals and output the n-bit mode configuration signals. In a case where S is a low level 0 and signals accessed by the n third mode configuration lines of the PUF array are all the low level 0, the PUF array is configured as the conventional SRAM storage mode, and at this moment, each of the PUF cells works in the conventional SRAM storage mode. In a case where S is a high level 1 and the signals accessed by the n third mode configuration lines of the PUF array are all the high level 1, the PUF array is configured as the PUF mode for generating the entropy source voltage, and at this moment, each of the PUF cells works in the PUF mode for generating the entropy source voltage. The decoding circuit has m output terminals and is configured to convert an address signal input thereto from the outside into an m-bit row selection signal, which is output by the m output terminals of the decoding circuit in one-to-one correspondence; and only one bit of the m-bit row selection signal is the high level 1, and the other bits of the m-bit row selection signal are all the low level 0. The reading circuit has a reference voltage input terminal, n left input ports, n right input ports, n left output ports and n right output ports. The n first mode signal output ports of the mode configuration circuit are connected to the n first mode configuration lines of the PUF array in one-to-one correspondence, the n second mode configuration output ports of the mode configuration circuit are connected to the n second mode configuration lines of the PUF array in one-to-one correspondence, n mode configuration signals from the outside are accessed by the n third mode configuration lines of the PUF array, the m output terminals of the decoding circuit are connected to the m word lines of the PUF array in one-to-one correspondence, the n left input ports of the reading circuit are connected to the n left bit lines of the PUF array in one-to-one correspondence, and the n right input ports of the reading circuit are connected to the n right bit lines of the PUF array in one-to-one correspondence. In a case where a high level 1 is accessed by one word line of the PUF array, a row of PUF cells corresponding to the word line are selected, an i^{th} PUF cell in the row outputs a voltage at the left bit line port thereof to an i^{th} left input port of the reading circuit by means of the i^{th} left bit line, the i^{th} PUF cell in the row outputs a voltage at the right bit line port thereof to an i^{th} right input port of the reading circuit by means of the i^{th} right bit line, and the reading circuit respectively compares the voltage accessed by the i^{th} left input port thereof and the voltage accessed by the i^{th} right input port thereof with a reference voltage accessed by the reference voltage input terminal thereof. If the voltage accessed by the i^{th} left input port of the reading circuit is greater than the reference voltage accessed by the reference voltage input terminal of the reading circuit, a digital signal 0 is output by an i^{th} left input port of the reading circuit; otherwise, a digital signal 1 is output by the i^{th} left input port of the reading circuit. If the voltage accessed by the i^{th} right input port of the reading circuit is greater than the reference voltage accessed by the reference voltage input terminal of the reading circuit, a digital signal 1 is output by an i^{th} right input port of the reading circuit; otherwise, a digital signal 0 is output by the i^{th} right input port of the reading circuit. As shown in FIG. 3, each PUF cell includes a first PMOS transistor P1, a second PMOS transistor P2, a third PMOS transistor P3, a first NMOS transistor N1, a second NMOS transistor N2, a third NMOS transistor N3, a fourth NMOS transistor N4, a fifth NMOS transistor N5 and a sixth NMOS transistor N6, wherein a gate of the first PMOS transistor P1 is the first mode configuration port of the PUF cell; a supply voltage VDD is accessed by a source of the first PMOS transistor P1; a drain of the first PMOS transistor P1, a source of the second PMOS transistor P2 and a source of the third PMOS transistor P3 are connected together; a gate of the second PMOS transistor P2, a gate of the second NMOS transistor N2, a drain of the third PMOS transistor P3, a drain of the third NMOS transistor N3, a drain of the fourth NMOS transistor N4 and a drain of the sixth NMOS transistor N6 are connected together; a drain of the second PMOS transistor P2, a drain of the second NMOS transistor N2, a gate of the third PMOS transistor P3, a gate of the third NMOS transistor N3, a source of the fourth NMOS transistor N4 and a drain of the fifth NMOS transistor N5 are connected together; a source of the first NMOS transistor N1 is grounded, shown as the voltage VSS; a drain of the first NMOS transistor N1, a source of the second NMOS transistor N2 and a source of the third NMOS transistor N3 are connected together; a gate of the first NMOS transistor N1 is the second mode configuration port of the PUF cell; a gate of the fourth NMOS transistor N4 is the third mode configuration port of the PUF cell; a gate of the fifth NMOS transistor N5 and a gate of the sixth NMOS transistor N6 are connected together, and a connecting terminal thereof is the word line port of the PUF cell; the source of the fifth NMOS transistor N5 is the left bit line port of the PUF cell; and a source of the sixth NMOS transistor N6 is the right bit line port of the PUF cell.

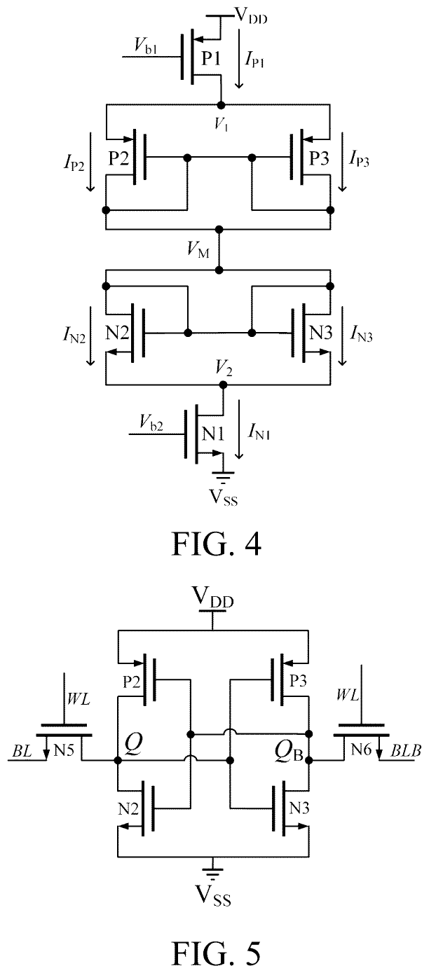

In this embodiment, the sub-threshold monostable PUF circuit with an SRAM function and an entropy source extraction function is constructed by the mode configuration circuit, the decoding circuit, the PUF array and the reading circuit; the PUF array has a conventional SRAM storage mode and a PUF mode for generating an entropy source voltage; the PUF array includes m*n PUF cells and n pre-charge modules; and each PUF cell includes the first PMOS transistor P1, the second PMOS transistor P2, the third PMOS transistor P3, the first NMOS transistor N1, the second NMOS transistor N2, the third NMOS transistor N3, the fourth NMOS transistor N4, the fifth NMOS transistor N5 and the sixth NMOS transistor N6. In a case where the PUF array is configured as the PUF mode for generating the entropy source voltage, the n first mode output ports of the mode configuration circuit output a same voltage signal, which is denoted as V_{b1}, and the n second mode output ports of the mode configuration circuit also output a same voltage signal, which is denoted as V_{b2}, wherein V_{b1} is greater than V_{b2}, V_{b1} is less than a threshold voltage of the first PMOS transistor P1, and V_{b2} is less than a threshold voltage of the first NMOS transistor N1; at this moment, the voltage signal V_{b1} is accessed by the first mode configuration port of each PUF cell in the PUF array, the voltage signal V_{b2} is accessed by the second mode configuration port of each PUF cell in the PUF array, each PUF cell in the PUF array works in the PUF mode for generating the entropy source voltage, and an equivalent circuit is shown in FIG. 4; at this moment, in each PUF cell, the voltage signal V_{b1} is accessed by the gate of the first PMOS transistor P1, and the voltage signal V_{b2} is accessed by the gate of the first NMOS transistor N1; because V_{b1} is less than the threshold voltage of the first PMOS transistor P1 and V_{b2} is less than the threshold voltage of the first NMOS transistor N1, the first PMOS transistor P1 and the first NMOS transistor N1 are not turned on and located in a deep sub-threshold region, currents across the first PMOS transistor P1 and the first NMOS transistor N1 are weak sub-threshold currents, the sub-threshold current across the first PMOS transistor P1 is denoted as I_{P1}, the sub-threshold current across the first NMOS transistor N1 is denoted as I_{N1}, and I_{P1} and I_{N1} are merely at the nA level; because the second PMOS transistor P2 and the third PMOS transistor P3 are connected in parallel and the first PMOS transistor P1 is connected in series with the second PMOS transistor P2 and the third PMOS transistor P3, the current I_{P1} across the first PMOS transistor P1 is equal to the sum of a current I_{P2} across the second PMOS transistor P2 and a current I_{P3} across the third PMOS transistor P3 according to the Kirchhoff's Current Law, and limited by the current I_{P1}, the current I_{P2} and the current I_{P3} are also weak sub-threshold currents, which force the second PMOS transistor P2 and the third PMOS transistor P3 to enter the deep sub-threshold region; and under the combined action of the currents I_{P1}, I_{P2} and I_{P3}, a matching voltage V₁ is generated at a joint of the drain of the first PMOS transistor P1, the source of the second PMOS transistor P2 and the source of the third PMOS transistor P3. Similarly, the current I_{N1} across the first NMOS transistor N1 is equal to the sum of a current I_{N2} across the second NMOS transistor and a current I_{N3} across the third NMOS transistor, and limited by the current I_{N1}, the currents I_{N2} and I_{N3} are also weak sub-threshold currents, which force the second NMOS transistor N2 and the third NMOS transistor N3 to enter the deep sub-threshold region; under the combined action of the currents I_{N1}, I_{N2} and I_{N3}, a matching voltage V₂ is generated at a joint of the drain of the first NMOS transistor N1, the source of the second NMOS transistor N3 and the source of the third NMOS transistor N3; the sum of the current I_{P2} across the second PMOS transistor P2 and the current I_{P3} across the third PMOS transistor P3 is equal to the sum of the current I_{N2} across the second NMOS transistor N2 and a current I_{N4} across the fourth NMOS transistor N4, and an entropy source voltage V_{M} in the PUF mode is generated at a joint of the drain of the second PMOS transistor P2, the drain of the third PMOS transistor P3, the drain of the second NMOS transistor N2 and the drain of the third NMOS transistor N3, in conjunction with the matching voltages V₁ and V₂; V_{M} is related to process parameters of the first PMOS transistor P1, the second PMOS transistor P2, the third PMOS transistor P3, the first NMOS transistor N1, the second NMOS transistor N2 and the third NMOS transistor N3, process deviations are inevitably introduced in the actual chip fabrication process, and these process deviations, particularly the difference between threshold voltages, change randomly and are amplified by the source-induced barrier lowering effect, leading to a large voltage distribution of V_{M}. After each PUF cell in the PUF array generates the entropy source voltage, all the pre-charge modules of the PUF array perform a pre-charge operation to refresh charges of all the left bit lines and all the right bit lines of the PUF array to keep voltages of all the left bit lines and all the right bit lines of the PUF array equal, and then, all the pre-charge modules stop the pre-charge operation; the decoding circuit outputs an m-bit row selection signal to select n PUF cells in one row of the PUF array, the entropy source voltage V_{M} generated by each of the selected PUF cells is transmitted by the fifth NMOS transistor N5 and the sixth NMOS transistor N6 to the left bit line and the right bit line connected to the PUF cell, at this moment, the entropy source voltage generated by the PUF cell, in the i^{th} column, of the n selected PUF cells is accessed by the i^{th} right bit line and the i^{th} left bit line of the PUF array, corresponding entropy source voltages are accessed by each left input port and each right input port of the reading circuit, and the reading circuit digitizes the entropy source voltages accessed by the n left input ports and the n right input ports to obtain a PUF response, which is then output. After the PUF response is output, all the pre-charge modules of the PUF array perform the pre-charge operation again to refresh the charges of all the left bit lines and all the right bit lines of the PUF array to keep the voltages of all the left bit lines and all the right bit lines of the PUF array equal, and then, all the pre-charge modules stop the pre-charge operation then, the decoding circuit outputs again an m-bit row selection signal; and this process is repeated until a desired number of PUF responses are output.

In a case where the PUF array is configured as the conventional SRAM storage mode, the n first mode output ports of the mode configuration circuit output a low level 0, and the n second mode output ports of the mode configuration circuit output a high level 1; at this moment, the low level 0 is accessed by the first mode configuration ports of all the PUF cells in the PUF array, and the high level 1 is accessed by the second mode configuration ports of all the PUF cells in the PUF array; at this moment, the first PMOS transistor P1 and the first NMOS transistor N1 are turned on and completely equivalent to a wire, each PUF cell in the PUF array works in the conventional SRAM storage mode, and an equivalent circuit is shown in FIG. 5; the second PMOS transistor P2, the third PMOS transistor P3, the second NMOS transistor N2 and the third NMOS transistor N3 in each PUF cell form a pair of cross-coupled inverters with a positive feedback function, wherein a joint of the drain of the second PMOS transistor P2 and the drain of the second NMOS transistor N2 is a left data storage node, which is denoted as Q; a joint of the drain of the third PMOS transistor P3 and the drain of the third NMOS transistor N3 is a right data storage node, which is denoted as QB; the PUF cells are equivalent to conventional SRAM cells; when a data write operation is performed, an external write circuit transmits an n-bit data signal to the n left bit lines and the n right bit lines of the PUF array, the decoding circuit outputs an m-bit row selection signal to select n PUF cells in one row of the PUF array, and each of the selected PUF cells transmits data to the left storage node Q and the right storage node QB of each PUF cell working in the conventional SRAM storage mode by means of the fifth NMOS transistor N5 and the sixth NMOS transistor N6; when a hold operation is performed, the decoding circuit does not output a signal, the fifth NMOS transistor N5 and the sixth NMOS transistor N6 of each PUF cell in the PUF array are turned off, and data (voltages) on the left storage node Q and the right storage node QB are held under the effect of positive feedback of the cross-coupled inverters; before data reading, all the pre-charge modules of the PUF array perform the pre-charge operation to refresh charges of all the left bit lines and all the right bit lines of the PUF array to keep voltages of all the left bit lines and all the right bit lines equal, and then, all the pre-charge modules stop the pre-charge operation; the decoding circuit outputs an m-bit row selection signal to select n PUF cell in one row of the PUF array; in each of the selected PUF cells, the data are transmitted from the left storage node Q and the right storage node QB to the left bit line and the right bit line connected to the PUF cell by means of the fifth NMOS transistor N5 and the sixth NMOS transistor N6; at this moment, the data on the left storage node Q and the right storage node QB of the PUF cell, in the i^{th} column, of the n selected PUF cells are accessed by the i^{th} left bit line and the i^{th} right bit line of the PUF array, and corresponding data are accessed by each left input port and each right input port of the reading circuit; the reading circuit digitizes data currently accessed by the n left input ports and the n right input ports thereof into corresponding data, which are then output. After the data are output, all the pre-charge modules of the PUF array perform the pre-charge operation again to refresh the charges of all the left bit lines and all the right bit lines of the PUF array to keep the voltages of all the left bit lines and all the right bit lines of the PUF array equal, and then, all the pre-charge modules stop the pre-charge operation; then, the decoding circuit outputs again an m-bit row selection signal; and the process is repeated until all data are read.

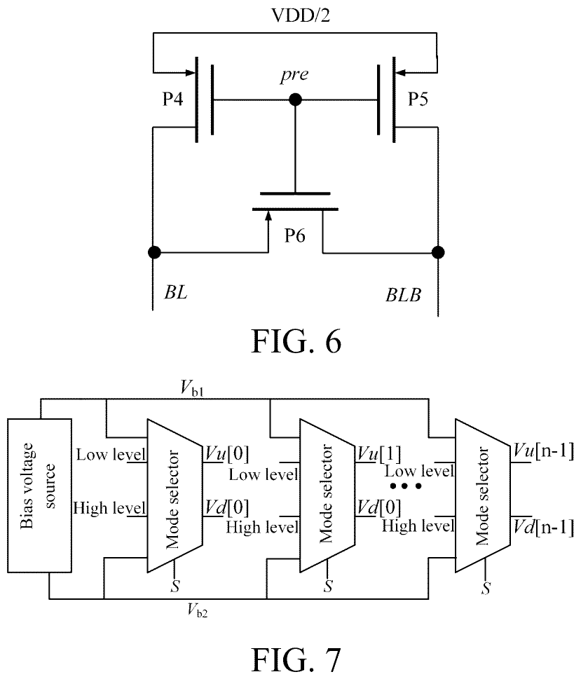

Embodiment 2: This embodiment is basically the same as Embodiment 1 and is different from Embodiment 1 in the following aspect: as shown in FIG. 6, in this embodiment, each pre-charge module includes a fourth PMOS transistor P4, a fifth PMOS transistor P5 and a sixth PMOS transistor P6, wherein a gate of the fourth PMOS transistor P4, a gate of the fifth PMOS transistor P5 and a gate of the sixth PMOS transistor P6 are connected together, and a connecting terminal thereof is the pre-charge control port of the pre-charge module; half of a supply voltage VDD/2 is accessed by a source of the fourth PMOS transistor P4 and a source of the fifth PMOS transistor P5; a drain of the fourth PMOS transistor P4 and a source of the sixth PMOS transistor P6 are connected together, and a connecting terminal thereof is the left pre-charge port of the pre-charge module; and a drain of the fifth PMOS transistor P5 and a drain of the sixth PMOS transistor P6 are connected together, and a connecting terminal thereof is the right pre-charge port of the pre-charge module.

In this embodiment, when a pre-charge operation needs to be performed on the PUF array, a low level 0 is accessed by the pre-charge control ports of the PUF array, that is, the low level 0 is accessed by the pre-charge control port of each pre-charge module; at this moment, in each pre-charge module, the fourth PMOS transistor P4, the fifth PMOS transistor P5 and the sixth PMOS transistor P6 are turned on, and half of the supply voltage VDD/2 is transmitted to the left pre-charge port and the right pre-charge port of each pre-charge module, that is, the left pre-charge port and the right pre-charge port of each pre-charge module output half of the supply voltage VDD/2. Thus, the n pre-charge modules refresh the voltages of the n left bit lines and the n right bit lines of the PUF array to half of the supply voltage VDD/2.

Embodiment 3: This embodiment is basically the same as Embodiment 2 and is different from Embodiment 2 in the following aspect: as shown in FIG. 7, in this embodiment, the mode configuration circuit includes a bias voltage source and n mode selectors, wherein the bias voltage source has a first bias voltage output port and a second bias voltage output port; each mode selector has a low level access port, a high level access port, a first bias voltage access port, a second bias voltage access port, a mode selection signal port, a first mode signal output port and a second mode signal output port; a low level 0 is accessed by the low level access port of each mode selector, and a high level 1 is accessed by the high level access port of each mode selector; the first bias voltage output port of the bias voltage source is connected to the first bias voltage access ports of the n mode selectors; the second bias voltage output port of the bias voltage source is connected to the second bias voltage access ports of the n mode selectors; the mode selection signal ports of the n mode selectors are connected, and a connecting terminal thereof is the mode selection port of the mode configuration circuit; the first mode signal output ports of the n mode selectors are used as the n first mode signal output ports of the mode configuration circuit; and the second mode signal output ports of the n mode selectors are used as the n second mode signal output ports of the mode configuration circuit.

In this embodiment, in a case where a low level 0 is accessed by the mode selection port of the mode configuration circuit, the first mode signal output port of each mode selector of the mode configuration circuit outputs the low level 0, the second mode signal output port of each mode selector of the mode configuration circuit outputs a high level 1, and the PUF array is configured as the conventional SRAM mode; and in a case where a high level 1 is accessed by the mode selection port of the mode configuration circuit, the first bias voltage output port of the bias voltage source outputs a voltage signal V_{b1}, the second bias voltage output port of the bias voltage source outputs a voltage signal V_{b2}, at this moment, the first mode signal output port of each mode selector outputs the voltage signal V_{b1}, the second mode signal output port of each mode selector outputs the voltage signal V_{b2}, and the PUF array is configured as the PUF mode for generating the entropy source voltage.

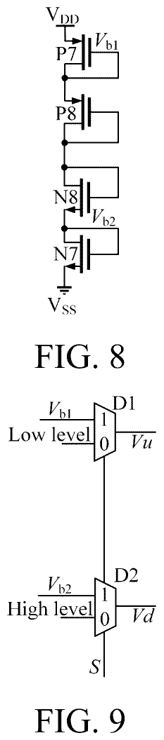

Embodiment 4: This embodiment is basically the same as Embodiment 3 and is different from Embodiment 3 in the following aspect: as shown in FIG. 8, in this embodiment, the bias voltage source includes a seventh PMOS transistor P7, an eighth PMOS transistor P8, a seventh NMOS transistor N7 and an eighth NMOS transistor N8, wherein a supply voltage VDD is accessed by a source of the seventh PMOS transistor P7; a gate of the seventh PMOS transistor P7, a drain of the seventh PMOS transistor P7 and a source of the eighth PMOS transistor P8 are connected together, and a connecting terminal thereof is the first bias voltage output port of the bias voltage source; a gate of the eighth PMOS transistor P8, a drain of the eighth PMOS transistor P8, a drain of the eighth NMOS transistor N8 and a gate of the eighth NMOS transistor N8 are connected together; a gate of the seventh NMOS transistor N7, a drain of the seventh NMOS transistor N7 and a source of the eighth NMOS transistor N8 are connected together, and a connecting terminal thereof is the second bias voltage output port of the bias voltage source; and a source of the seventh NMOS transistor is grounded shown as the voltage VSS.

According to the bias voltage source in this embodiment, because the bias voltage source, the seventh PMOS transistor P7, the eighth PMOS transistor P8, the seventh NMOS transistor N7 and the eighth NMOS transistor N8 are connected in series and stacked, currents across the seventh PMOS transistor P7, the eighth PMOS transistor P8, the seventh NMOS transistor N7 and the eighth NMOS transistor N8 are equal. Under the TSMC 65 nm process used by the sub-threshold monostable PUF circuit with an SRAM function and an entropy source extraction function provided by the present invention, threshold voltages of all the PMOS transistors and the NMOS transistors are greater than 400 mv, and the supply voltage VDD is generally 1.2 V, such that the sum of threshold voltages of the bias voltage source, the seventh PMOS transistor P7, the eighth PMOS transistor P8, the seventh NMOS transistor N7 and the eighth NMOS transistor N8 is less than the voltage of the supply voltage VDD, currents across the seventh PMOS transistor P7, the eighth PMOS transistor P8, the seventh NMOS transistor N7 and the eighth NMOS transistor N6 are sub-threshold currents, and under the action of the sub-threshold currents, the first bias voltage output port of the bias voltage source generates a voltage signal V_{b1} and the second bias voltage output port of the bias voltage source generates a voltage signal V_{b2}.

Embodiment 5: This embodiment is basically the same as Embodiment 3 and is different from Embodiment 3 in the following aspect: as shown in FIG. 9, each mode selector includes two multiplexers, wherein each multiplexer has a first input port, a second input port, a selection terminal and an output terminal; in a case where a high level is accessed by the selection terminal, the first input port is connected to the output terminal; in a case where a low level is accessed by the selection terminal, the second input port is connected to the output terminal; and the two multiplexers are referred to as a first multiplexer D1 and a second multiplexer D2, respectively, the first input port of the first multiplexer D1 is the first bias voltage access port of the mode selector, the second input port of the first multiplexer D1 is the low level access port of the mode selector, the first input port of the second multiplexer D2 is the second bias voltage access port of the mode selection, and the second input port of the second multiplexer D2 is the high level access port of the mode selector.

In this embodiment, in a case where a high level is accessed by the selection terminal of each mode selector, an output signal of the output terminal of the first multiplexer D1 is a voltage signal V_{b1}, and an output signal of the output terminal of the second multiplexer D2 is a voltage signal V_{b2}; and in a case where a low level is accessed by the selection terminal of each mode selector, the output signal of the output terminal of the first multiplexer D1 is a low level, and the output signal of the output terminal of the second multiplexer D2 is a high level.

To verify the performance of the sub-threshold monostable PUF circuit with an SRAM function and an entropy source extraction function provided by the present invention, design of the sub-threshold monostable PUF circuit with an SRAM function and an entropy source extraction function provided by the present invention is completed by Cadence virtuoso software and simulation is performed on the sub-threshold monostable PUF circuit with an SRAM function and an entropy source extraction function provided by the present invention by SPECTRE, under TSMC 65 nm process. The sub-threshold monostable PUF circuit with an SRAM function and an entropy source extraction function provided by the present invention is evaluated according to test results of three common evaluation indicators, which are respectively randomness, uniqueness and reliability.

### 1. Randomness

The randomness is generally evaluated by a National Institute of Standards and Technology (NIST) test. In the NIST test, the randomness of output responses of the PUF circuit is often evaluated by a p-value. If the p-value is greater than 0.01, the PUF responses will be considered as random in this test, and the confidence of randomness will be higher with the increase in the p-value. NIST tests are performed on the sub-threshold monostable PUF circuit with an SRAM function and an entropy source extraction function provided by the present invention (limited by the number of bits of PUF responses, tests with extremely high requirements for the length of a bit string cannot be performed), and test results are shown in Table 1.

TABLE 1
NIST test results

| | | | Average | |
|---|---|---|---|---|
| NIST test | Stream length(n) | No. of Runs | p-value | Pass(%) |
| Frequency | 256 | 40 | 0.4326 | 97.5% |
| Block Frequency | 256 | 40 | 0.4871 | 95% |
| Runs | 256 | 40 | 0.5616 | 100% |
| Longest Runs | 256 | 40 | 0.4199 | 100% |
| FFT | 256 | 40 | 0.4092 | 97.5% |
| Non Overlapping | 256 | 40 | 0.5173 | 100% |
| Template | | | | |
| Serial | 256 | 40 | 0.5204 | 98.75% |
| Approximate | 256 | 40 | 0.5495 | 100% |
| Entropy | | | | |
| Cumclative | 256 | 40 | 0.4493 | 96.25% |
| Sums | | | | |

It may be known, by analyzing data in Table 1, that the sub-threshold monostable PUF circuit with an SRAM function and an entropy source extraction function provided by the present invention passes all applicable NIST tests and has a high average p-value, showing good randomness.

### 2. Uniqueness

The uniqueness indicates the difference between different PUF circuit entities and is generally evaluated by the inter-Hamming distance. In an ideal condition, the PUF circuit entities are mutually independent, that is, the Hamming distance of the PUF circuit entities is 50%. The average Hamming distance of K PUF circuit entities may be calculated by formula (1):

$$E ( H {D}_{inter} ) = \frac{2}{k ( k - 1 )} {\sum }_{u = 1}^{k - 1} {\sum }_{v = u + 1}^{k} \frac{H D ( {R}_{u} , {R}_{v} )}{n} \times 100 \% \qquad ( 1 )$$

where, k indicates the number of PUF circuit entities, and Rᵤ and Rᵥ respectively indicate an n-bit PUF response generated by a u^{th} PUF circuit entity and an n-bit PUF response generated by a v^{th} PUF circuit entity under a same challenge.

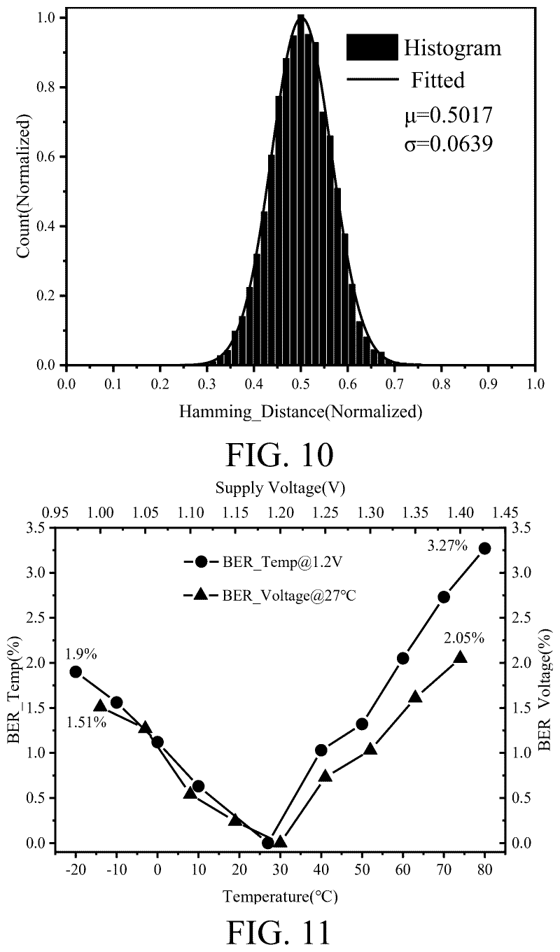

Under the nominal condition (1.2V, 27° C.), the inter-Hamming distances of PUF responses output by performing 40 times of Monte Carlo simulation on the sub-threshold monostable PUF circuit with an SRAM function and an entropy source extraction function provided by the present invention are obtained, as shown in FIG. 10. It may be known, by analyzing the pattern of FIG. 10, that a mathematical expectation of the uniqueness of the sub-threshold monostable PUF circuit with an SRAM function and an entropy source extraction function provided by the present invention is 50.17% and a standard deviation of the uniqueness of the sub-threshold monostable PUF circuit with an SRAM function and an entropy source extraction function is 0.0639, indicating that the sub-threshold monostable PUF circuit with an SRAM function and an entropy source extraction function provided by the present invention have good discrimination.

### 3. Reliability

The reliability is of great importance for PUF circuits because it ensures that the PUF circuits still generate consistent outputs even under the condition of aging caused by environmental changes (such as temperature and voltage fluctuations) and long-term use. The variation, with temperature and voltage, of the bit error rate of the sub-threshold monostable PUF circuit with an SRAM function and an entropy source extraction function provided by the present invention is shown in Table 11. It may be known, by analyzing the pattern of FIG. 11, that in case of drastic changes of the temperature and voltage, the maximum bit error rates of the sub-threshold monostable PUF circuit with an SRAM function and an entropy source extraction function provided by the present invention are 3.27% and 2.05%, respectively, indicating that the sub-threshold monostable PUF circuit with an SRAM function and an entropy source extraction function has good reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A sub-threshold monostable PUF circuit with an SRAM function and an entropy source extraction function, comprising a mode configuration circuit, a decoding circuit, a PUF array and a reading circuit,
wherein the PUF array has a SRAM storage mode and a PUF mode for generating an entropy source voltage, and the PUF array includes m*n PUF cells and n pre-charge modules,
wherein * is a multiplication operator, m=2^{P}, n=2^{K}, P and K are positive integers; the m*n PUF cells are distributed in m rows and n columns, the n pre-charge modules are distributed in one row and n columns, and each PUF cell has a left bit line port, a right bit line port, a first mode configuration port, a second mode configuration port, a third mode configuration port and a word line port; each pre-charge module has a left pre-charge port, a right pre-charge port and a pre-charge control port; the left bit line ports of the m PUF cells in an i^{th} column are connected to the left pre-charge port of the pre-charge module in the i^{th} column with a connecting line forming an i^{th} left bit line of the PUF array, which is denoted as BL[i−1], and i=1, 2, . . . , n; the right bit line ports of the m PUF cells in the i^{th} column are connected to the right pre-charge port of the pre-charge module in the i^{th} column with a connecting line forming an i^{th} right bit line of the PUF array, which is denoted as BLB[i−1]; the first mode configuration ports of the m PUF cells in the i^{th} column are connected together with a connecting line forming an i^{th} first mode configuration line of the PUF array, which is denoted as Vu[i−1]; the second mode configuration ports of the m PUF cells in the i^{th} column are connected together with a connecting line forming an i^{th} second mode configuration line of the PUF array, which is denoted as Vd[i−1]; the third mode configuration ports of the m PUF cells in the i^{th} column are connected together with a connecting line forming an i^{th} third mode configuration line of the PUF array, which is denoted as E[i−1]; the word line ports of the n PUF cells in a j^{th} row are connected together with a connecting line forming a j^{th} word line of the PUF array, which is denoted as WL[j−1], and j=1, 2, . . . , m; and the pre-charge control ports of the n pre-charge modules are connected together, and a connecting terminal of the pre-charge control ports is a pre-charge control port of the PUF array,
wherein the mode configuration circuit has a mode selection port, n first mode signal output ports and n second mode signal output ports, wherein a mode selection signal S is accessed by the mode selection port of the mode configuration circuit, and under the control of the mode selection signal S, the n first mode signal output ports and the n second mode signal output ports of the mode configuration circuit respectively generate corresponding n-bit mode configuration signals and output the n-bit mode configuration signals,
wherein in a case where the mode selection signal S is a low level 0 and signals accessed by the n third mode configuration lines of the PUF array are all the low level 0, the PUF array is configured as the SRAM storage mode, and at this moment, each of the PUF cells works in the SRAM storage mode,
wherein in a case where the mode selection signal S is a high level 1 and the signals accessed by the n third mode configuration lines of the PUF array are all the high level 1, the PUF array is configured as the PUF mode for generating the entropy source voltage, and at this moment, each of the PUF cells works in the PUF mode for generating the entropy source voltage,
where the decoding circuit has m output terminals and is configured to convert an address signal input thereto from the outside into an m-bit row selection signal, which is output by the m output terminals of the decoding circuit in one-to-one correspondence; and only one bit of the m-bit row selection signal is the high level 1, and the other bits of the m-bit row selection signal are all the low level 0,
wherein the reading circuit has a reference voltage input terminal, n left input ports, n right input ports, n left output ports and n right output ports,
wherein the n first mode signal output ports of the mode configuration circuit are connected to the n first mode configuration lines of the PUF array in one-to-one correspondence, the n second mode configuration output ports of the mode configuration circuit are connected to the n second mode configuration lines of the PUF array in one-to-one correspondence, n mode configuration signals from the outside are accessed by the n third mode configuration lines of the PUF array, the m output terminals of the decoding circuit are connected to the m word lines of the PUF array in one-to-one correspondence, the n left input ports of the reading circuit are connected to the n left bit lines of the PUF array in one-to-one correspondence, and the n right input ports of the reading circuit are connected to the n right bit lines of the PUF array in one-to-one correspondence,
wherein in a case where the high level 1 is accessed by one word line of the PUF array, a row of PUF cells corresponding to the word line are selected, an i^{th} PUF cell in the row outputs a voltage at the left bit line port of the i^{th} PUF cell to an i^{th} left input port of the reading circuit through the i^{th} left bit line, the i^{th} PUF cell in the row outputs a voltage at the right bit line port of the i^{th} PUF cell to an i^{th} right input port of the reading circuit through the i^{th} right bit line, and the reading circuit respectively compares the voltage accessed by the i^{th} left input port of the i^{th} PUF cell and the voltage accessed by the i^{th} right input port of the i^{th} PUF cell with a reference voltage accessed by the reference voltage input terminal of the reading circuit,
wherein if the voltage accessed by the i^{th} left input port of the reading circuit is greater than the reference voltage accessed by the reference voltage input terminal of the reading circuit, a digital signal 0 is output by an i^{th} left output port of the reading circuit; otherwise, a digital signal 1 is output by the i^{th} left input port of the reading circuit,
wherein if the voltage accessed by the i^{th} right input port of the reading circuit is greater than the reference voltage accessed by the reference voltage input terminal of the reading circuit, the digital signal 1 is output by an i^{th} right input port of the reading circuit; otherwise, the digital signal 0 is output by the i^{th} right input port of the reading circuit, and
wherein each PUF cell includes a first PMOS transistor, a second PMOS transistor, a third PMOS transistor, a first NMOS transistor, a second NMOS transistor, a third NMOS transistor, a fourth NMOS transistor, a fifth NMOS transistor and a sixth NMOS transistor, wherein a gate of the first PMOS transistor is the first mode configuration port of the PUF cell; a supply voltage VDD is accessed by a source of the first PMOS transistor; a drain of the first PMOS transistor, a source of the second PMOS transistor and a source of the third PMOS transistor are connected together; a gate of the second PMOS transistor, a gate of the second NMOS transistor, a drain of the third PMOS transistor, a drain of the third NMOS transistor, a drain of the fourth NMOS transistor and a drain of the sixth NMOS transistor are connected together; a drain of the second PMOS transistor, a drain of the second NMOS transistor, a gate of the third PMOS transistor, a gate of the third NMOS transistor, a source of the fourth NMOS transistor and a drain of the fifth NMOS transistor are connected together; a source of the first NMOS transistor is grounded which is voltage VSS; a drain of the first NMOS transistor, a source of the second NMOS transistor and a source of the third NMOS transistor are connected together; a gate of the first NMOS transistor is the second mode configuration port of the PUF cell; a gate of the fourth NMOS transistor is the third mode configuration port of the PUF cell; a gate of the fifth NMOS transistor and a gate of the sixth NMOS transistor are connected together, and a connecting terminal of the gates of the fifth NMOS transistor and the sixth NMOS transistor is the word line port of the PUF cell; a source of the fifth NMOS transistor is the left bit line port of the PUF cell; and a source of the sixth NMOS transistor is the right bit line port of the PUF cell.

2. The sub-threshold monostable PUF circuit with the SRAM function and the entropy source extraction function according to claim 1, wherein each pre-charge module includes a fourth PMOS transistor, a fifth PMOS transistor and a sixth PMOS transistor, wherein a gate of the fourth PMOS transistor, a gate of the fifth PMOS transistor and a gate of the sixth PMOS transistor are connected together, and a connecting terminal of the gates of the fourth PMOS transistor, the fifth PMOS transistor and the sixth PMOS transistor is the pre-charge control port of the pre-charge module; half of the supply voltage VDD/2 is accessed by a source of the fourth PMOS transistor and a source of the fifth PMOS transistor; a drain of the fourth PMOS transistor and a source of the sixth PMOS transistor are connected together, and a connecting terminal of the drain of the fourth PMOS transistor and the source of the sixth PMOS transistor is the left pre-charge port of the pre-charge module; and a drain of the fifth PMOS transistor and a drain of the sixth PMOS transistor are connected together, and a connecting terminal of the drain of the fifth PMOS transistor and the drain of the sixth PMOS transistor is the right pre-charge port of the pre-charge module.

3. The sub-threshold monostable PUF circuit with the SRAM function and the entropy source extraction function according to claim 1, wherein the mode configuration circuit includes a bias voltage source and n mode selectors, wherein the bias voltage source has a first bias voltage output port and a second bias voltage output port; each mode selector has a low level access port, a high level access port, a first bias voltage access port, a second bias voltage access port, a mode selection signal port, a first mode signal output port and a second mode signal output port; the low level 0 is accessed to the low level access port of each mode selector, and the high level 1 is accessed to the high level access port of each mode selector; the first bias voltage output port of the bias voltage source is connected to the first bias voltage access ports of the n mode selectors; the second bias voltage output port of the bias voltage source is connected to the second bias voltage access ports of the n mode selectors; the mode selection signal ports of the n mode selectors are connected together, and a connecting terminal of the mode selection signal ports is the mode selection port of the mode configuration circuit; the first mode signal output ports of the n mode selectors are used as the n first mode signal output ports of the mode configuration circuit; and the second mode signal output ports of the n mode selectors are used as the n second mode signal output ports of the mode configuration circuit.

4. The sub-threshold monostable PUF circuit with the SRAM function and the entropy source extraction function according to claim 3, wherein the bias voltage source includes a seventh PMOS transistor, an eighth PMOS transistor, a seventh NMOS transistor and an eighth NMOS transistor, wherein the supply voltage VDD is accessed by a source of the seventh PMOS transistor; a gate of the seventh PMOS transistor, a drain of the seventh PMOS transistor and a source of the eighth PMOS transistor are connected together, and a connecting terminal of the gate of the seventh PMOS transistor, the drain of the seventh PMOS transistor and the source of the eighth PMOS transistor is the first bias voltage output port of the bias voltage source; a gate of the eighth PMOS transistor, a drain of the eighth PMOS transistor, a drain of the eighth NMOS transistor and a gate of the eighth NMOS transistor are connected together; a gate of the seventh NMOS transistor, a drain of the seventh NMOS transistor and a source of the eighth NMOS transistor are connected together, and a connecting terminal of the gate of the seventh NMOS transistor, the drain of the seventh NMOS transistor and the source of the eighth NMOS transistor is the second bias voltage output port of the bias voltage source; and a source of the seventh NMOS transistor is grounded which is voltage VSS.

5. The sub-threshold monostable PUF circuit with the SRAM function and the entropy source extraction function according to claim 3, wherein each mode selector includes two multiplexers, wherein each multiplexer has a first input port, a second input port, a selection terminal and an output terminal; in a case where the high level 1 is accessed by the selection terminal, the first input port is connected to the output terminal; in a case where the low level 0 is accessed by the selection terminal, the second input port is connected to the output terminal; and the two multiplexers comprises a first multiplexer and a second multiplexer, the first input port of the first multiplexer is the first bias voltage access port of the mode selector, the second input port of the first multiplexer is the low level access port of the mode selector, the first input port of the second multiplexer is the second bias voltage access port of the mode selection, and the second input port of the second multiplexer is the high level access port of the mode selector.
